(19) United States
(12) Patent Application Publication
(10) Pub. No.: US 2026/0123079 A1
(43) Pub. Date: Apr. 30, 2026

(54) IMAGE SENSING DEVICE INCLUDING LIGHT REFLECTIVE STRUCTURE

(71) Applicant: SK hynix Inc., Icheon-si (KR)

(72) Inventors: Nam Jae CHOI, Icheon-si (KR); Eun Khwang LEE, Icheon-si (KR)

(21) Appl. No.: 19/094,765

(22) Filed: Mar. 28, 2025

(30) Foreign Application Priority Data
Oct. 28, 2024 (KR) 10-2024-0148850

(51) Int. Cl. H10F 39/00; H10F 39/18

(52) U.S. Cl. CPC H10F 39/8067; H10F 39/182; H10F 39/8053; H10F 39/807

(57) ABSTRACT

An image sensing device includes a first optical filter and a second optical filter that are respectively disposed in two unit pixels; a first reflective structure disposed between the first optical filter and the second optical filter, and configured to include a first capping layer disposed to define a space operating as a first air region; and a second reflective structure disposed closer to boundaries of the two unit pixels as compared to the first reflective structure, and configured to include a second capping layer disposed to define a space operating as a second air region. The first reflective structure has first side surfaces facing each other and the second reflective structure has second side surfaces facing each other, and a first inclination angle of at least one of the first side surfaces is smaller than a second inclination angle of at least one of the second side surfaces.

### PRIORITY AND CROSS-REFERENCE TO RELATED APPLICATION

This patent document claims the priority and benefits of Korean patent application No. 10-2024-0148850, filed on Oct. 28, 2024, the disclosure of which is incorporated herein by reference in its entirety as part of the disclosure of this patent document.

### TECHNICAL FIELD

The technology and embodiments disclosed in this patent document generally relate to an image sensing device, and more particularly to an image sensing device including one or more light reflective structures.

### BACKGROUND

An image sensing device is a device that includes unit pixels for capturing optical images by converting incident light into electrical signals using a photosensitive semiconductor material which reacts to light. With the development of automotive, medical, computer and communication industries, the demand for high-performance image sensing devices is increasing in various fields such as smartphones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices. The CMOS image sensing devices are smaller in size and consume less power than the CCD image sensing devices. Furthermore, CMOS image sensing devices are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the present disclosure relate to an image sensing device that includes a light reflective structure configured to effectively address a crosstalk problem occurring between adjacent pixels in an image sensing device, and prevents collapse (or destruction) of the light reflective structure when pressure in an air region included in the light reflective structure increases.

In accordance with an embodiment of the present disclosure, an image sensing device may include: a first optical filter and a second optical filter that are respectively disposed in two unit pixels located adjacent to each other to filter incident light received by the two unit pixels, respectively, wherein each unit pixel is configured to detect incident light for image sensing; a first reflective structure disposed between the first optical filter and the second optical filter, and configured to include a first capping layer disposed to define a space filled with air and operating as a first air region, the first reflective structure having first side surfaces facing each other; and a second reflective structure disposed closer to boundaries of the two unit pixels as compared to the first reflective structure, and configured to include a second capping layer disposed to define a space filled with the air and operating as a second air region, the second reflective structure having second side surfaces facing each other, wherein the first and second reflective structures are structured so that a first inclination angle of at least one of the first side surfaces is smaller than a second inclination angle of at least one of the second side surfaces.

In some implementations, the second reflective structure may further include: an open region disposed between the first air region and the second air region.

In some implementations, the first reflective structure and the second reflective structure may be arranged to at least partially surround each of the first optical filter and the second optical filter.

In some implementations, the open region may be arranged along a top surface of the second reflective structure.

In some implementations, the second capping layer may contact at least a portion of the second air region; and the open region may be implemented by including a plurality of open sub-regions spaced apart from each other on a top surface of the second reflective structure.

In some implementations, an upper portion of the first side surface may be located closer to a center of the first reflective structure than a lower portion of the first side surface.

In some implementations, a lower portion of the second side surface may be located closer to a center of the second reflective structure than an upper portion of the second side surface.

In some implementations, an upper portion of the first side surface may be located closer to a center of the first reflective structure than a lower portion of the first side surface; and a lower portion of the second side surface may be located closer to a center of the second reflective structure than an upper portion of the second side surface.

In some implementations, an upper portion of the second capping layer disposed over the second side surface may have a smaller thickness than a lower portion of the second capping layer.

In some implementations, the first capping layer may include a material having a lower refractive index than each of a material included in the first optical filter and a material included in the second optical filter.

In accordance with another embodiment of the present disclosure, an image sensing device may include: a pixel array configured to include a first pixel and a second pixel that detect incident light for image sensing, the pixel array including a first reflective structure that extends along a boundary between the first pixel and the second pixel and a second reflective structure that is disposed in the first reflective structure and extends along the boundary between the first pixel and the second pixel, wherein the first reflective structure includes a first capping layer disposed to define a space filled with air and operating as a first air region surrounded by the first capping layer; the second reflective structure includes a second capping layer disposed to define a space filled with the air and operating as a second air region surrounded by the second capping layer; and the first and second reflective structures are structured to cause a first inclination angle formed by a bottom surface of the first reflective structure and a side surface of the first capping layer to be smaller than a second inclination angle, formed by the bottom surface and a side surface of the second capping layer.

In some implementations, the second capping layer may further include: an open region disposed between the first air region and the second air region and extending along the boundary.

In some implementations, the second capping layer may further include: a plurality of open regions disposed between the first air region and the second air region and spaced apart from each other.

In some implementations, the first and second reflective structures may be structured so that the first inclination angle may be an acute angle; and the second inclination angle may be a right angle.

In some implementations, the first and second reflective structures may be structured so that the first inclination angle may be a right angle; and the second inclination angle may be an obtuse angle.

In some implementations, the first and second reflective structures may be structured so that the first inclination angle may be an acute angle; and the second inclination angle may be an obtuse angle.

In some implementations, an upper portion of the side surface of the second capping layer may have a smaller thickness than a lower portion of the side surface of the second capping layer.

In some implementations, the first and second reflective structures may be structured to cause a refraction angle of incident light incident upon the first capping layer to be smaller than an incident angle at which refraction light obtained by refraction of the incident light is incident upon the second capping layer.

In some implementations, the pixel array may include: a center region located at a center of the pixel array; and an edge region spaced apart from the center region, wherein the first inclination angle of the edge region is larger than the first inclination angle of the center region.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a schematic diagram illustrating an example of a pixel array of an image sensing device based on some implementations of the present disclosure.

FIG. 2 is a schematic diagram illustrating an example of a pixel region shown in FIG. 1 based on some implementations of the present disclosure.

FIG. 3 is a plan view illustrating an example of a light reflective structure shown in FIG. 2 based on some implementations of the present disclosure.

FIG. 4 is a plan view illustrating another example of the light reflective structure shown in FIG. 2 based on some implementations of the present disclosure.

FIG. 5A is a cross-sectional view illustrating an example of a cross-section taken along the line B-B′ shown in FIG. 3 or FIG. 4 based on some implementations of the present disclosure.

FIG. 5B is a cross-sectional view illustrating an example of a cross-section taken along the line C-C′ shown in FIG. 3 based on some implementations of the present disclosure.

FIG. 5C is a cross-sectional view illustrating another example of a sidewall of a second reflective structure shown in FIG. 5A based on some implementations of the present disclosure.

FIG. 6 is a cross-sectional view illustrating another example of a cross-section taken along the line B-B′ shown in FIG. 3 or FIG. 4 based on some implementations of the present disclosure.

FIG. 7 is a cross-sectional view illustrating still another example of a cross-section taken along the line B-B′ shown in FIG. 3 or FIG. 4 based on some implementations of the present disclosure.

### DETAILED DESCRIPTION

This patent document provides embodiments and examples of an image sensing device including one or more light reflective structures that may be used in configurations to substantially address one or more technical or engineering issues and to mitigate limitations or disadvantages encountered in some image sensing devices in the art. Some embodiments of the present disclosure relate to an image sensing device that includes a light reflective structure configured to effectively address a crosstalk problem occurring between adjacent pixels in an image sensing device, and prevents collapse (or destruction) of the light reflective structure when pressure in an air region included in the light reflective structure increases. In recognition of the issues of the conventional image sensors, the embodiments of the present disclosure may provide an image sensing device that can prevent collapse of a light reflective structure, and effectively prevent crosstalk occurring between adjacent pixels, thereby increasing quantum efficiency.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

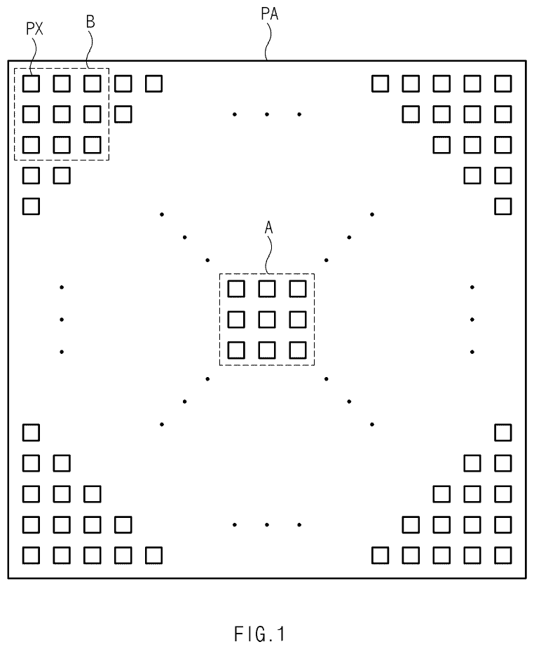

FIG. 1 is a schematic diagram illustrating an example of a pixel array (PA) of an image sensing device based on some implementations of the present disclosure.

Referring to FIG. 1, a pixel array (PA) may include a plurality of unit pixels (PXs) that detect incident light to capture images carried in the incident light.

A pixel array (PA) may include a plurality of unit pixels (PXs) arranged in a two-dimensional (2D) structure including rows and columns. Each of the plurality of unit pixels (PX) or two or more unit pixels (PXs) may share at least one element to implement a shared pixel structure, so that each unit pixel (PX) or at least two unit pixels (PXs) may convert optical signals into electrical signals on a shared pixel basis.

The plurality of unit pixels (PX) may be arranged in a plurality of rows in a row direction, and may be arranged in a plurality of columns in a column direction. Each of the unit pixels (PX) may include a photoelectric conversion element, an optical filter, a microlens, and predetermined pixel transistors.

The row direction may mean a horizontal direction shown in FIG. 1. The column direction may mean a vertical direction shown in FIG. 1.

The unit pixel (PX) may generate an electrical signal in response to incident light received by that unit pixel (PX). For example, a photoelectric conversion element in the unit pixel (PX) may generate photocharges in response to incident light, and the generated photocharges may be converted into a pixel signal (or an electrical signal) by the predetermined pixel transistors, so that the pixel signal is then output. The photoelectric conversion element can be implemented in various manners, for example, a photodiode, a photo transistor, a photo gate, or other photosensitive circuitry capable of converting light into a pixel signal (e.g., a charge, a voltage or a current). The predetermined pixel transistors may include, for example, at least one of a transfer transistor, a reset transistor, a source follower transistor, and a selection transistor.

The transfer transistor may move the photocharges generated by the photoelectric conversion element to a floating diffusion (FD) region, the source follower transistor may output a pixel signal corresponding to potential of the floating diffusion (FD) region, and the selection transistor may act as a switch for selecting which one of the unit pixels (PX) is to be used to output the pixel signal. The reset transistor may reset the potential of the floating diffusion (FD) region to a reference potential.

The pixel array (PA) may include a center region (A) and an edge region (B). The center region (A) may be a region that is located at the center of the pixel array (PA) and includes a plurality of pixels (PXs). The edge region (B) may be a region that is disposed along an edge of the pixel array and spaced apart from the center region (A). The edge region (B) includes the plurality of pixels (PXs).

Hereinafter, embodiments of the present disclosure will be described centering upon the center region (A), and the edge region (B) will be described by focusing on differences from the center region (A).

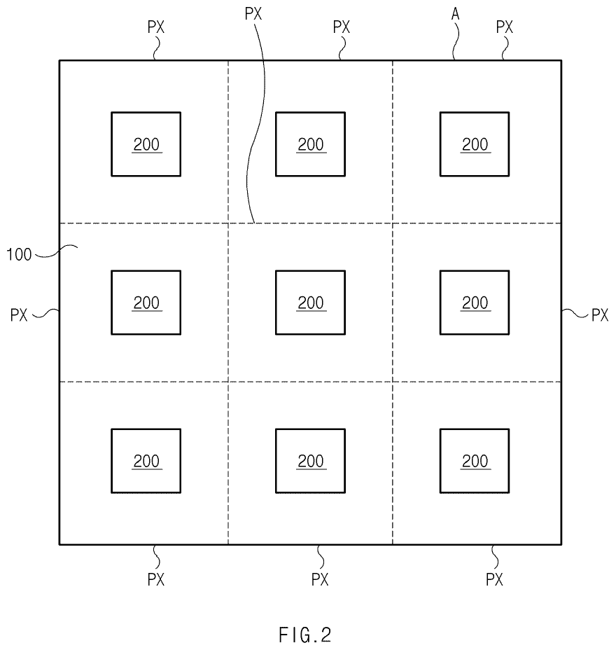

FIG. 2 is a schematic diagram illustrating an example of the center region (A) shown in FIG. 1 based on some implementations of the present disclosure.

Referring to FIGS. 1 and 2, the center region (A) may include nine unit pixels (PXs) arranged in a (3×3) matrix structure including 3 rows and 3 columns.

The center region (A) may include at least one light reflective structure 100 and at least one optical filter 200.

The optical filter 200 may act as a filter that selectively transmits at least a portion of incident light while blocking other portions of the incident. The plurality of optical filters 200 may be arranged adjacent to each other in a (3×3) matrix structure. In the example as shown in FIG. 2, the plurality of optical filters 200 is disposed at the center of the corresponding unit pixels (PXs). In the example, the light reflective structure 100 is disposed between the two optical filters 200 of the two adjacent unit pixels. The optical filter 200 may selectively transmit light having a specific wavelength. The optical filter 200 may selectively absorb or reflect light having wavelengths other than the specific wavelength. Based on the specific wavelength, the optical filter 200 may selectively transmit certain colors of light while absorbing or reflecting other colors of light. For example, the optical filter 200 may selectively transmit green light having a wavelength (e.g., a wavelength range of 500˜600 nm). In another example, the optical filter 200 may selectively transmit red light having a wavelength (e.g., a wavelength range of 600˜700 nm). In yet another example, the optical filter 200 may selectively transmit blue light having a wavelength (e.g., a wavelength range of 400˜500 nm).

The optical filter 200 configured to selectively transmit green light of the corresponding wavelength may be referred to as a green optical filter, the optical filter 200 configured to selectively transmit red light of the corresponding wavelength may be referred to as a red optical filter, and the optical filter 200 configured to selectively transmit blue light of the corresponding wavelength may be referred to as a blue optical filter. For example, the green optical filter, the red optical filter, and the blue optical filter may be arranged in a Bayer pattern. For example, the green optical filter, the red optical filter, and the blue optical filter may be arranged in a quad-Bayer pattern.

The light reflective structure 100 may include a material having high light reflectivity. For example, the light reflective structure 100 may include one or more air regions containing air. The light reflective structure 100 may be arranged between adjacent optical filters 200. The light reflective structure 100 may be arranged in a grid shape (e.g., a square mesh shape). The light reflective structure 100 may be arranged along a boundary surface between the plurality of pixels (PXs). The light reflective structure 100 may reduce optical crosstalk between adjacent optical filters 200.

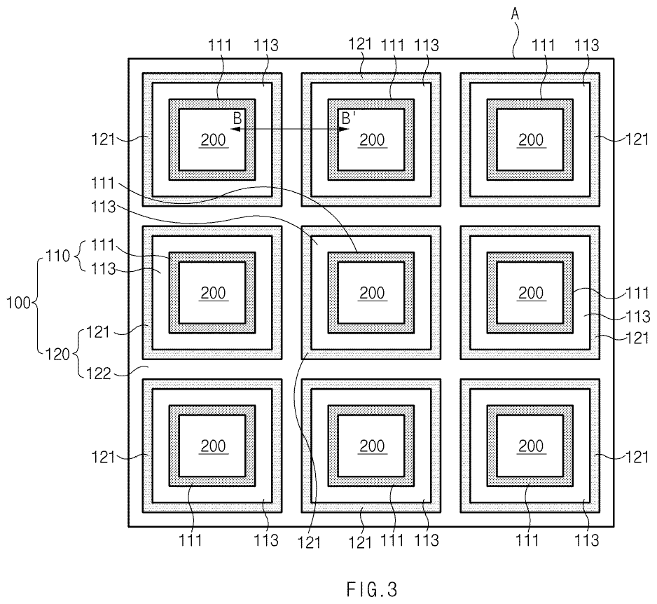

FIG. 3 is a schematic diagram illustrating an example (hereinafter referred to as a first embodiment) of the light reflective structure 100 shown in FIG. 2 based on some implementations of the present disclosure.

Referring to FIGS. 2 and 3, the light reflective structure 100 according to the first embodiment of the present disclosure may include a first reflective structure 110 and a second reflective structure 120.

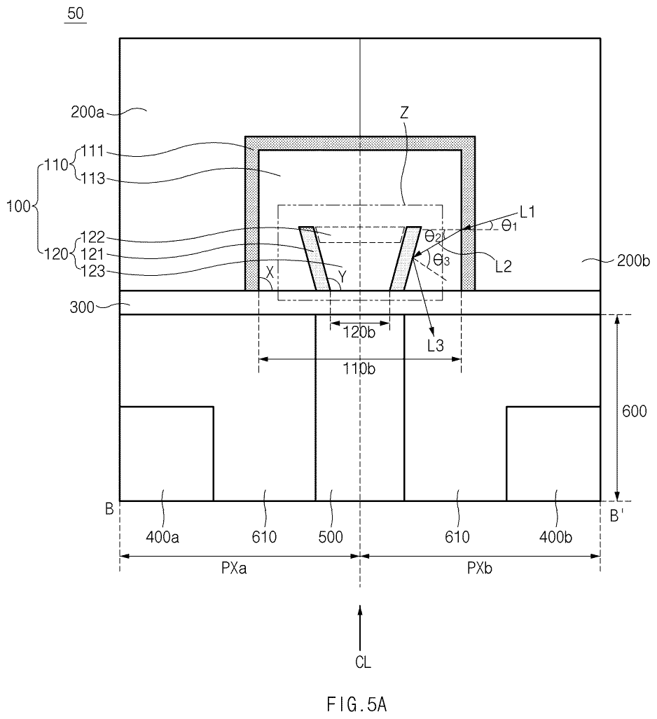

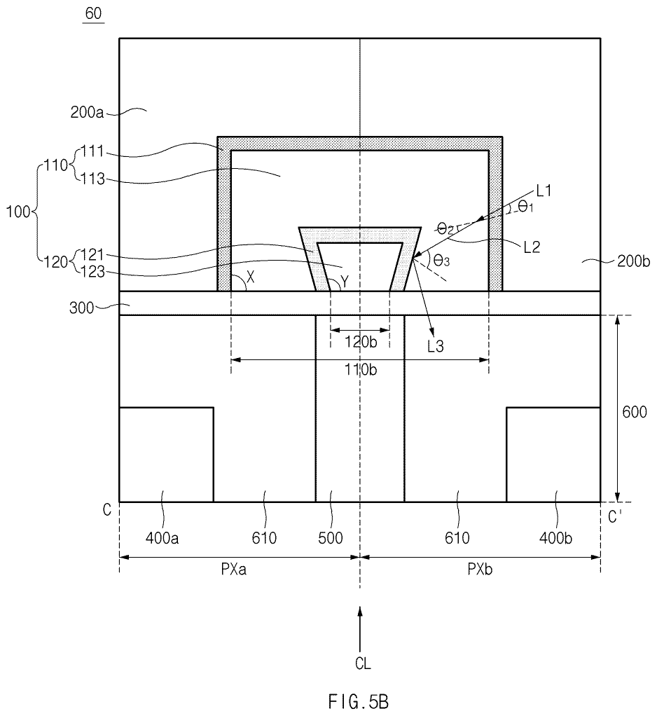

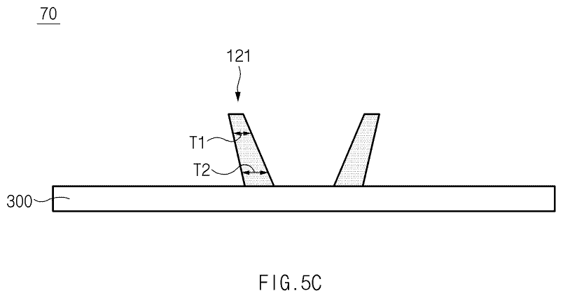

FIG. 3 is an exemplary plan view showing a light reflective structure shown in FIG. 2 based on the first embodiment (e.g., a plan view at a height where the open region 122 of FIG. 5A is located).

The first reflective structure 110 may include a first capping layer 111 and a first air region 113. The first capping layer 111 may be disposed along a boundary of the optical filters 200 and structure to define a space to be filled with air and operate as the first air region 113. The first reflective structure 110 may have a shape surrounding each of the plurality of optical filters 200. The first reflective structure 110 may reflect light incident from the optical filter 200 to the first reflective structure 110 to reduce optical crosstalk between adjacent optical filters 200.

The first capping layer 111 may surround each of the optical filters 200. For example, the first capping layer 111 may contact each surface of the optical filters 200, and may surround each of the optical filters 200. The first air region 113 may be a region that is in contact with the first capping layer 111. The first air region 113 may be a region disposed between the first capping layer 111 and the second capping layer 121. The first air region 113 may be a region containing air.

The second reflective structure 120 may include a second capping layer 121, an open region 122, and a second air region (123 of FIG. 5A). The second reflective structure 120 may be arranged along the first air region 113, and may have a grid structure. The second reflective structure 120 may reflect incident light that is not reflected by the first reflective structure 110, thereby reducing optical crosstalk between adjacent optical filters 200.

The second capping layer 121 may cap at least both sides of the second reflective structure 120. The second capping layer 121 may be spaced apart from each of the optical filters 200, and may have a shape that surrounds each of the optical filters 200.

The open region 122 may be arranged between two facing (or opposite) side surfaces of the second capping layer 121. The open region 122 may be spaced apart from each of the optical filters 200, and may have a shape that surrounds each of the optical filters 200 and the grid structure. The open region 122 may be arranged as the grid structure along the top surface of the second reflective structure 120. In some implementations, the open region 122 and the second air region 123 may form the top portion and the bottom portion of the second reflective structure 120, respectively.

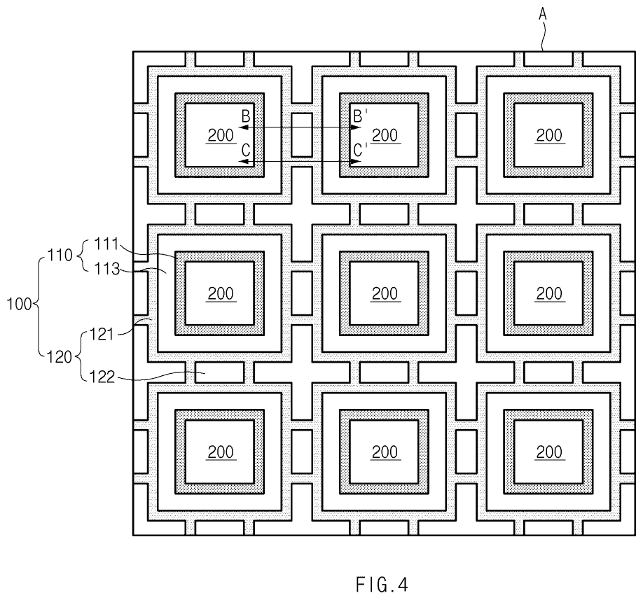

FIG. 4 is a plan view illustrating another example (hereinafter referred to as a second embodiment) of the light reflective structure 100 shown in FIG. 2 based on some implementations of the present disclosure.

Hereinafter, the differences between FIG. 3 and FIG. 4 will be described in detail.

Referring to FIGS. 2 to 4, the light reflective structure 100 according to the second embodiment of the present disclosure may include a first reflective structure 110 and a second reflective structure 120.

The first reflective structure 110 of the second embodiment may be substantially the same as the first reflective structure 110 of the first embodiment.

The second reflective structure 120 may include a second capping layer 121, an open region 122, and a second air region 123 (see FIG. 5A).

An example of the second capping layer 121 of FIG. 4 is shown in the plan view (e.g., FIG. 5A or 5B) of the top surface of the second capping layer 121 of the second embodiment. The second capping layer 121 of FIG. 4 may further include a portion for interconnecting the second capping layers 121 facing each other shown in FIG. 3.

The open regions 122 may be implemented as a plurality of open regions 122 so that the plurality of open regions 122 may be spaced apart from each other within the top surface of the second capping layer 121. The shape of each of the open regions 122 may be, for example, a rectangular shape or a cross shape as shown in FIG. 4, but the shape of each open region 122 is not limited thereto. Although FIG. 4 illustrates an embodiment in which the open regions 122 are arranged at regular intervals, the scope of the pattern in which the open regions 122 are arranged is not limited to FIG. 4, and other implementations are also possible.

A cross-sectional structure of the light reflective structure 100 will be described later with reference to FIGS. 5A to 7.

FIG. 5A is a cross-sectional view illustrating an example of a cross-section taken along the line B-B′ shown in FIG. 3 or FIG. 4 based on some implementations of the present disclosure.

Referring to FIGS. 2, 3, and 5A, the first cross-section 50 may be an example cross-section taken along the line B-B′ of FIG. 3 or FIG. 4.

The first cross-section 50 may include a light reflective structure 100, a first optical filter 200a, a second optical filter 200b, an anti-reflection layer 300, and a substrate region 600.

The light reflective structure 100 may include a first reflective structure 110 and a second reflective structure 120. The light reflective structure 100 may be arranged between the first optical filter 200a and the second optical filter 200b. The light reflective structure 100 may be disposed over the anti-reflection layer 300.

The first reflective structure 110 may include a first capping layer 111 and a first air region 113. The first reflective structure 110 may have at least portions extending along the first optical filter 200a and the second optical filter 200b. The first reflective structure 110 may extend along a boundary surface (e.g., an interface) between the plurality of pixels (PXs) shown in FIG. 2.

The first capping layer 111 may be disposed to form a first inclination angle (X°) with respect to an imaginary line parallel to a surface of the substrate 600. In some implementations, the first capping layer 111 may include a side surface that has the first inclination angle (X°) with respect to a surface contacting a first bottom surface 110b of the first reflective structure 110. The first capping layer 111 may further include the first bottom surface 110b for interconnecting the lowermost ends of the side surfaces of the first capping layer 111 that face to each other. The first inclination angle (X°) may be an internal angle formed by the first bottom surface 110b and the side surface of the first capping layer 111.

The first capping layer 111 may be structured to define a space to be filled with air and the space operates as the first air region 113. Thus, the first capping layer 111 contacts the side surface and the top surface of the first air region 113. The first capping layer 111 may surround the first air region 113. The first capping layer 111 may include a material having a lower refractive index than the material included in the first optical filter 200a and the second optical filter 200b.

When the first reflective structure 110 may be disposed between the first optical filter 200a and the second optical filter 200b, the first reflective structure 100 may have first side surfaces that face to each other. One of the first side surfaces of the first reflective structure 100 may be disposed close to the first optical filter 200a and the other of the first side surfaces of the first reflective structure 100 may be disposed close to the second optical filter 200b. The first inclination angle (X°) may be a right angle, but may vary based on variables or limitations in a fabrication process. The upper portion of the first side surface may maintain the same distance from the lower portion of the second side surface to the center of the first reflective structure 110, but may vary due to variables and limitations in the fabrication process. The center line (CL) may be an example of the center of the first reflective structure 110. The center line (CL) may coincide with a boundary surface between the plurality of pixels (PX), but may vary within an error range due to variables or limitations in the fabrication process.

The first air region 113 may be a region filled with air. The first air region 113 may be a region having a space specified or defined by the first capping layer 111. The first air region 113 may be formed in a grid shape aligned with the grid shape of the light reflective structure 100 of FIG. 2.

The second reflective structure 120 may include a second capping layer 121, an open region 122, and a second air region 123. The second reflective structure 120 may be structured to define spaces for the open region 122 and the second air region 123. The second reflective structure 120 may be arranged in the internal space provided by the first reflective structure 110. The second reflective structure 120 may extend along the boundary surface between the pixels (PXs) of FIG. 2. The top surface of the second reflective structure 120 may include an open region 122 disposed between the first air region 113 and the second air region 123. The open region 122 may include an air. The open region 122 may be a region filled with air. The open region 122 may be a region connecting the first air region 113 and the second air region 123. The open region 122 may be arranged at a same height as a top surface of the second capping layer 121 of FIG. 5B. The open region 122 may be a region having the same thickness of the top surface of the second capping layer 121.

When the second reflective structure 120 may be disposed between the first optical filter 200a and the second optical filter 200b, the second reflective structure 120 may have second side surfaces that face to each other. For example, at some portions of the second capping layer 121 may form the second side surfaces of the second reflective structure 120. For example, the second capping layer 121 may contact at least both side surfaces of the second reflective structure 120. The second capping layer 121 may be disposed to form a second inclination angle (Y°) with respect to an imaginary line parallel to a surface of the substrate 600. In some implementations, the second capping layer 121 may include a side surface having a second inclination angle (Y°) from the second bottom surface 120b of the second reflective structure 120. The second bottom surface 120b may be a surface for interconnecting the lowermost ends of two opposing side surfaces of the second capping layer 121. The second inclination angle (Y°) may be an internal angle formed by the second bottom surface 120b and the side surface of the second capping layer 121.

The first bottom surface 110b and the second bottom surface 120b are separated from each other to define the first inclination angle (X°) and the second inclination angle (Y°), respectively, other implementations are also possible, and it should be noted that the first bottom surface 110b and the second bottom surface 120b may also be located as one bottom surface on the same plane.

The second capping layer 121 may contact the side surfaces and the top surface of the second air region 123. For example, a portion of the top surface of the second air region 123 may contact the second capping layer 121. The other portion of the top surface of the second air region 123 may contact the open region 122. The second capping layer 121 may surround the second air region 123. The second capping layer 121 may include a material having a lower refractive index than the material included in the first optical filter 200a and the second optical filter 220b.

The second inclination angle (Y°) may be an obtuse angle. The second reflective structure 120 may include a second side surface near the first optical filter 200a, and the lower portion of the second side surface may be closer to the center of the second reflective structure 120 than the upper portion of the second side surface. The center line (CL) may be an example of the center of the second reflective structure 120. In addition, the lower portion of the second capping layer 121 may be closer to the center of the second reflective structure 120 than the upper portion of the second capping layer 121.

The first inclination angle (X°) may be smaller than the second inclination angle (Y°).

Although the present disclosure has disclosed an example embodiment in which the center of the first reflective structure 110 coincides with the center of the second reflective structure 120 for convenience of description, other implementations are also possible without being limited thereto.

The open region 122 may be disposed between the first air region 113 and the second air region 123. The open region 122 may define an outer edge of the second reflective structure 120 together with the second capping layer 121 surrounding at least both side surfaces of the second air region 123. When the temperature of the inside of the image sensing device increases, the air included in the second air region 123 expands, so that the open region 122 may prevent collapse of the second isolation structure 120 (or collapse of the second capping layer 122).

The second air region 123 may be a region distinguished from the first air region 113. In some implementations, both side surfaces of the second air region 123 are covered by the second capping layer 123. The second air region 123 may include air.

As the reflective structure provides a double structure containing the air by including the first air region 113 and the second air region 123, light reflectivity of the light reflective structure 100 can increase, and quantum efficiency (QE) of the unit pixels (PXs) can also increase.

For example, the first capping layer 111 includes a material having a lower refractive index than the first optical filter 200a and the second optical filter 200b, and the first capping layer 111 caps air having a relatively low refractive index, so that incident light may be reflected by the first capping layer 111.

In some cases, however, there may be incident light (L1) that is not reflected by the first capping layer 111 and penetrates the first capping layer 111 depending on an incident angle (i.e., an angle of incidence). It is assumed that the incident angle of the incident light (L1) is denoted by ‘θ₁’. In addition, light obtained when the incident light (L1) penetrates the first capping layer 111 and is then refracted will hereinafter be referred to as ‘refraction light (L2)’, and a refraction angle of the incident light (L1) will hereinafter be referred to as a refraction angle (θ₂). The incident angle of the refraction light (L2) incident upon the second capping layer 121 will hereinafter be referred to as ‘θ₃’, and light reflected by the second capping layer 121 will hereinafter be referred to as ‘reflection light (L3)’.

The refraction angle (θ₂) of the incident light (L1) incident upon the first side surface or the first capping layer 111 of the first reflective structure 110 may be smaller than the incident angle (θ₃) of the refraction light (L2) incident upon the second side surface or the second capping layer 121 of the second reflective structure 120.

When the first side surface (or the side surface of the first capping layer 111) and the second side surface (or the side surface of the second capping layer 121) are parallel to each other, the refraction angle (θ₂) may be equal to the incident angle (θ₃). However, the first inclination angle (X°) and the second inclination angle (Y°) are different from each other, and in particular, the second inclination angle (Y°) has a larger value than the first inclination angle (X°), so that the refraction angle (θ₂) may have a smaller value than the incident angle (θ₃). Thus, the incident angle (θ₃) may be larger than the incident angle obtained when the two side surfaces (capping layers) are parallel to each other. Total reflection may occur when the incident angle is larger than a critical angle (i.e., a threshold angle). Therefore, as the incident angle (θ₃) increases, the reflection ratio of the refraction light (L2) to be reflected by the second side surface (or the side surface of the second capping layer 121) may further increase.

When the incident light (L1) that sequentially penetrates the second optical filter 200b and the first capping layer 111 is reflected by the second capping layer 121, and the reflection light (L3) is incident upon the second photoelectric conversion element 400b included in the second pixel (PXb) rather than the first pixel (PXa) adjacent to the second pixel (PXb), the quantum efficiency (QE) may further increase.

The first optical filter 200a may be disposed in the first pixel (PXa) and may transmit light having a specific wavelength. The second optical filter 200b may be disposed in the second pixel (PXb). The first optical filter 200a and the second optical filter 200b may be adjacent to each other. Each of the first optical filter 200a and the second optical filter 200b may be an example of the optical filter 200 shown in FIG. 2.

The anti-reflection layer 300 may be arranged over the substrate region 600. The anti-reflection layer 300 may include a material (e.g., tungsten W) having high light transmittance. The anti-reflection layer 300 may include a stacked structure (not shown) in which a plurality of layers is stacked.

The substrate region 600 may include a first photoelectric conversion element 400a, a second photoelectric conversion element 400b, a pixel isolation structure 500, and a semiconductor region 610.

The first photoelectric conversion element 400a may be disposed in the first pixel (PXa), and may generate photocharges in response to incident light. The second photoelectric conversion element 400b may be disposed in the second pixel (PXb), and may generate photocharges in response to incident light.

The pixel isolation structure 500 may be disposed in the substrate region 600 and between the first pixel (PXa) and the second pixel (PXb). The pixel isolation structure 600 may operate as optical barriers to prevent the light incident on one of the first pixel (PXa) and the second pixel (PXb) from reaching the other of the first pixel (PXa) and the second pixel (Pxb). The pixel isolation structure 500 may prevent light incident upon the first pixel (PXa) from reaching or penetrating the second pixel (PXb). The pixel isolation structure 500 may prevent light incident upon the second pixel (PXb) within the substrate region 600 from reaching or penetrating the first pixel (PXa).

The semiconductor region 610 may refer to a region that remains after the photoelectric conversion elements (400a, 400b) and the pixel isolation structure 500 are arranged.

FIG. 5B is a cross-sectional view illustrating an example of a cross-section taken along the line C-C′ shown in FIG. 4 based on some implementations of the present disclosure.

Hereinafter, the embodiment of FIG. 5B will be described centering upon different structural characteristics from those of FIG. 5A.

Referring to FIG. 4 and FIGS. 5A and 5B, the second cross-section 60 is substantially the same as the first cross-section 50 shown in FIG. 5A except for some differences, and as such redundant description thereof will herein be omitted for brevity.

Unlike the first cross-section 50, the second capping layer 121 in the second cross-section 60 may be disposed connect both side surfaces of the second air region 123. The second capping layer 121 may further contact the top surface of the second air region 123.

FIG. 5C is a cross-sectional view illustrating another example of a sidewall of the second reflective structure 121 shown in FIG. 5A based on some implementations of the present disclosure.

Referring to FIG. 3 and FIGS. 5A and 5C, the second capping layer 121 in the third cross-section 70 may be disposed over the anti-reflection layer 300.

Although the center of gravity of the second capping layer 121 in the first cross-section 50 deviates from the bottom surface of the second reflective structure 121, the second capping layer 121 may not collapse due to adhesive force with the anti-reflection layer 300. However, there is a risk that the second capping layer 121 may collapse if the above adhesive force weakens over time or due to external impact.

In order to prevent collapse of the second capping layer 121, as in the third cross-section 70, a thickness (T1) of the upper portion of the second capping layer 121 may be smaller than a thickness (T2) of the lower portion of the second capping layer 121. That is, the thickness (T2) of the lower portion of the second capping layer 121 may be designed to be larger, and collapse of the second capping layer 121 may be prevented.

In particular, as can be seen from the light reflective structure 100 of the first embodiment illustrated in FIG. 3, the second capping layers 121 are spaced apart from each other, a design change as in FIG. 5C may be more effective in terms of stability of the second capping layer 121.

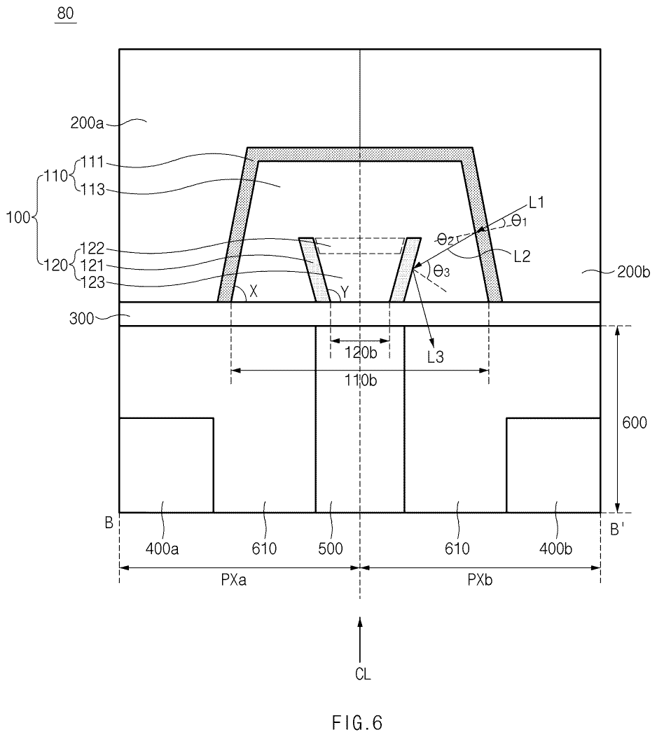

In addition, the thickness (T1) of the upper portion of the second capping layer 121 shown in FIGS. 5A and 6 may be smaller than the thickness (T2) of the lower portion of the second capping layer 121 shown in FIG. 5C.

The upper or lower portion of each of the capping layers (111, 121) described above does not necessarily mean only the uppermost or lowermost end, but may also mean whether the corresponding layer is located at a relatively high or low position.

FIG. 6 is a cross-sectional view illustrating another example of a cross-section taken along the line B-B′ shown in FIG. 3 or FIG. 4 based on some implementations of the present disclosure.

Hereinafter, description of content overlapping with FIG. 5A will herein be omitted for brevity, and the embodiment of FIG. 6 will be described centering upon different structural characteristics from those of FIG. 5A.

Referring to FIG. 3 and FIGS. 5A and 6, the first inclination angle (X) of the fourth cross-section 80, which is another example of the cross-section taken along the line B-B′ shown in FIG. 3, may have an acute angle. In a first side surface (or the side surface of the first capping layer 111) of the first reflective structure 110, the upper portion of the first side surface may be closer to the center of the first reflective structure 110 than the lower portion of the first side surface. The upper portion of the first capping layer 111 may be closer to the center of the first reflective structure 110 than the lower portion of the first capping layer 111.

According to the embodiment of FIG. 6, the lower portion of the second side surface may also be closer to the center of the second reflective structure 120 than the upper portion of the second side surface. The embodiment in which the first inclination angle (X°) is an acute angle and the second inclination angle (Y°) is an obtuse angle may have a higher reflectivity in the second capping layer 121 than the embodiment of FIG. 5A. The first inclination angle (X°) may be smaller than the second inclination angle (Y°).

In addition, when the fourth cross-section 80 is applied to the cross-section taken along the line B-B′ of the second embodiment of FIG. 4, the structural characteristics in which the second capping layer 121 is in closer contact with the top surface of the second air region 123 as shown in FIG. 5B may be substantially equally applied to the cross-section taken along the line C-C′ of the second embodiment.

That is, referring to FIG. 4 and FIGS. 5A and 6, the cross-section taken along the line C-C′ of FIG. 4 may be designed so that the second capping layer 121 can contact both side surfaces of the second air region 123 at the fourth cross-section 80, and the second capping layer 121 can further contact the top surface of the second air region 123.

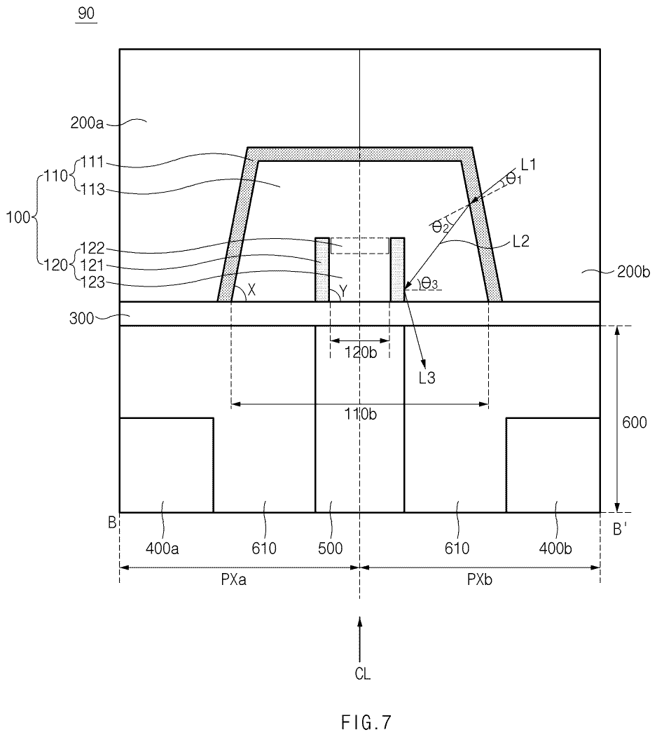

FIG. 7 is a cross-sectional view illustrating still another example of a cross-section taken along the line B-B′ shown in FIG. 3 or FIG. 4 based on some implementations of the present disclosure.

Hereinafter, description of content overlapping with FIG. 5A will herein be omitted for brevity, and the embodiment of FIG. 7 will be described centering upon different structural characteristics from those of FIG. 5A.

Referring to FIGS. 3, 5A, 6, and 7, the second inclination angle (Y°) of the fifth cross-section 90, which is another example of the cross-section taken along the line B-B′ of FIG. 3, may be a right angle, and may vary due to variables or limitations in the fabrication process. In addition, the first inclination angle (X°) of the third cross-section 70 may have an acute angle. The first inclination angle (X°) may be smaller than the second inclination angle (Y°).

According to the embodiment having the fifth cross-section 90, the incident angle (θ₃) has a larger value than the refraction angle (θ₂), so that light reflectivity in the second capping layer 121 increases, and the second capping layer 121 may be stably formed without collapsing.

In addition, when the fifth cross-section 90 is applied to the cross-section taken along the line B-B′ of the second embodiment of FIG. 4, the structural characteristics in which the second capping layer 121 is in closer contact with the top surface of the second air region 123 as shown in FIG. 5B may be substantially equally applied to the cross-section taken along the line C-C′ of the second embodiment.

That is, referring to FIG. 4 and FIGS. 5A and 7, the cross-section taken along the line C-C′ of FIG. 4 may be designed so that the second capping layer 121 can contact both side surfaces of the second air region 123 at the fifth cross-section 90, and the second capping layer 121 can further contact the top surface of the second air region 123.

In addition, the above description of the size range of the first inclination angle (X°) and the second inclination angle (Y°) may vary due to variables or limitations in the fabrication process.

The present disclosure illustrates various embodiments in which the first inclination angle (X°) is smaller than the second inclination angle (Y°). In particular, although representative examples of the present disclosure include the first embodiment in which the first inclination angle (X°) is a right angle and the second inclination angle (Y°) is an obtuse angle, the second embodiment in which the first inclination angle (X°) is an acute angle and the second inclination angle (Y°) is an obtuse angle, and the third embodiment in which the first inclination angle (X°) is an acute angle and the second inclination angle (Y°) is a right angle, the scope or spirit of the present disclosure is not limited thereto, and it should be noted that other embodiments in which the first inclination angle (X°) is smaller than the second inclination angle (Y°) may also be included in the present disclosure.

For example, the first inclination angle (X°) may be an acute angle and the second inclination angle (Y°) may be an acute angle larger than the first inclination angle (X°). For example, the first inclination angle (X°) may be an obtuse angle and the second inclination angle (Y°) may be an obtuse angle larger than the first inclination angle (X°).

In addition, although the light reflective structure 100 extending along the boundary surface between the pixels (PXs) located in the center region (A of FIG. 2) has been described, there may be some differences from the light reflective structure 100 extending along the boundary surface between the pixels (PXs) located in the edge region (B of FIG. 2).

Referring to FIGS. 1 to 7, the incident light (L1) may not be incident at the same angle upon all pixels (PXs) arranged in the pixel array (PA of FIG. 1). In particular, the incident light (L1) in the edge region (B) may be incident upon the pixels (PXs) at a relatively more oblique angle than in the center region (A). In this case, when the first inclination angle (X°) is constant in both the edge region (B) and the center region (A), the edge region (B) may have a smaller incident angle (θ₁) than the center region (A).

As the incident angle (θ₁) decreases, the incident light (L1) is not totally reflected and can penetrate the first capping layer 111. In order to address this issue, the first inclination angle (X°) obtained when the first pixel (PXa) and the second pixel (PXb) are located in the center region (A of FIG. 2) may be designed differently from the first inclination angle (X°) obtained when the first pixel (PXa) and the second pixel (PXb) are located in the edge region (B of FIG. 2).

For example, the first inclination angle (X°) in the edge region (B) may be greater than the first inclination angle (X°) in the center region (A). All of the embodiments shown in FIGS. 5A, 5B, 5, 6 and 7 can also be modified in a manner that the first inclination angle (X°) in the edge region (B) is greater than the first inclination angle (X°) in the center region (A) without departing from the scope or spirit of the present disclosure.

As is apparent from the above description, the image sensing device according to the embodiments of the present disclosure may prevent collapse of a light reflective structure, may effectively prevent crosstalk that may occur between adjacent pixels, thereby increasing quantum efficiency.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a first optical filter and a second optical filter that are respectively disposed in two unit pixels located adjacent to each other to filter incident light received by the two unit pixels, respectively, wherein each unit pixel is configured to detect incident light for image sensing;
a first reflective structure disposed between the first optical filter and the second optical filter, and configured to include a first capping layer disposed to define a space filled with air and operating as a first air region, the first reflective structure having first side surfaces facing each other; and
a second reflective structure disposed closer to boundaries of the two unit pixels as compared to the first reflective structure, and configured to include a second capping layer disposed to define a space filled with the air and operating as a second air region, the second reflective structure having second side surfaces facing each other,
wherein the first and second reflective structures are structured so that
a first inclination angle of at least one of the first side surfaces is smaller than a second inclination angle of at least one of the second side surfaces.

2. The image sensing device according to claim 1, wherein the second reflective structure further includes:
an open region between the first air region and the second air region.

3. The image sensing device according to claim 2, wherein:
the first reflective structure and the second reflective structure are arranged to at least partially surround each of the first optical filter and the second optical filter.

4. The image sensing device according to claim 3, wherein:
the open region is arranged along a top surface of the second reflective structure.

5. The image sensing device according to claim 3, wherein:
the second capping layer contacts at least a portion of the second air region; and
the open region is implemented by including a plurality of open sub-regions spaced apart from each other on a top surface of the second reflective structure.

6. The image sensing device according to claim 1, wherein:
an upper portion of the first side surface is located closer to a center of the first reflective structure than a lower portion of the first side surface.

7. The image sensing device according to claim 1, wherein:
a lower portion of the second side surface is located closer to a center of the second reflective structure than an upper portion of the second side surface.

8. The image sensing device according to claim 1, wherein:
an upper portion of the first side surface is located closer to a center of the first reflective structure than a lower portion of the first side surface; and
a lower portion of the second side surface is located closer to a center of the second reflective structure than an upper portion of the second side surface.

9. The image sensing device according to claim 1, wherein:
an upper portion of the second capping layer disposed over the second side surface has a smaller thickness than a lower portion of the second capping layer.

10. The image sensing device according to claim 1, wherein:
the first capping layer includes a material having a lower refractive index than each of a material included in the first optical filter and a material included in the second optical filter.

11. An image sensing device comprising:
a pixel array configured to include a first pixel and a second pixel that detect incident light for image sensing, the pixel array including a first reflective structure that extends along a boundary between the first pixel and the second pixel and a second reflective structure that is disposed in the first reflective structure and extends along the boundary between the first pixel and the second pixel,
wherein
the first reflective structure includes a first capping layer disposed to define a space filled with air and operating as a first air region surrounded by the first capping layer;
the second reflective structure includes a second capping layer disposed to define a space filled with the air and operating as a second air region surrounded by the second capping layer; and
the first and second reflective structures are structured to cause a first inclination angle formed by a bottom surface of the first reflective structure and a side surface of the first capping layer to be smaller than a second inclination angle, formed by the bottom surface and a side surface of the second capping layer.

12. The image sensing device according to claim 11, wherein the second capping layer further includes:
an open region disposed between the first air region and the second air region and extending along the boundary.

13. The image sensing device according to claim 11, wherein the second capping layer further includes:
a plurality of open regions disposed between the first air region and the second air region and spaced apart from each other.

14. The image sensing device according to claim 11, wherein the first and second reflective structures are structured so that:
the first inclination angle is an acute angle; and
the second inclination angle is a right angle.

15. The image sensing device according to claim 11, wherein the first and second reflective structures are structured so that:
the first inclination angle is a right angle; and
the second inclination angle is an obtuse angle.

16. The image sensing device according to claim 11, wherein the first and second reflective structures are structured so such:
the first inclination angle is an acute angle; and
the second inclination angle is an obtuse angle.

17. The image sensing device according to claim 11, wherein:
an upper portion of the side surface of the second capping layer has a smaller thickness than a lower portion of the side surface of the second capping layer.

18. The image sensing device according to claim 11, wherein the first and second reflective structures are structured to cause a refraction angle of incident light incident upon the first capping layer to be smaller than an incident angle at which refraction light obtained by refraction of the incident light is incident upon the second capping layer.

19. The image sensing device according to claim 11, wherein the pixel array includes:
a center region located at a center of the pixel array; and
an edge region spaced apart from the center region,
wherein the first inclination angle of the edge region is larger than the first inclination angle of the center region.
